(19) United States
(12) Patent Application Publication
(10) Pub. No.: US 2007/0176105 A1
(43) Pub. Date: Aug. 2, 2007

(54) PHOTOSENSITIVE DIAGNOSTIC DEVICE

(76) Inventors: Igor Trofimov, Long Valley, NJ (US); Stephen A. Lyon, Plainsboro, NJ (US)

Correspondence Address: DINSMORE & SHOHL LLP, ONE DAYTON CENTRE, ONE SOUTH MAIN STREET, SUITE 1300, DAYTON, OH, 45402-2023, US

(21) Appl. No.: 11/622,704

(22) Filed: Jan. 12, 2007

Related U.S. Application Data
(60) Provisional application No. 60/758,815, filed on Jan. 13, 2006.

(51) Int. Cl. G01J 5/02; H01L 27/14; G01J 5/20; H01L 31/00

(52) U.S. Cl. 250/339.11; 250/341.8; 250/338.4

(57) ABSTRACT

The present invention relates to a photosensitive diagnostic device configured to project an optical signal, capture reflected portions of the optical signal, and convert the captured portions of the optical signal into an electrical signal indicative of characteristics of a sample analyzed by the device. In accordance with one embodiment, a photosensitive diagnostic device comprises an illumination source and a detector. The illumination source comprises an output face configured to project an optical signal characterized by at least one diagnostic frequency. The detector comprises a photosensitive input face configured to capture reflected portions of the optical signal. The photosensitive input face of the detector is further configured to convert the captured portions of the optical signal into one or more electrical signals at least partially representing a degree of change in the diagnostic frequency of the optical signal. The output face of the illumination source and the photosensitive input face of the detector lie in a substantially common plane. The present invention further relates to a diagnostic system comprising an embodiment of the photosensitive diagnostic device herein described.

### CROSS-REFERENCE TO RELATED APPLICATIONS

This application claims the benefit of U.S. Provisional Application Ser. No. 60/758,815, filed Jan. 13, 2006.

### BRIEF SUMMARY OF THE INVENTION

The present invention relates generally to a photosensitive diagnostic device configured to project an optical signal, capture reflected portions of the optical signal, and convert the captured portions of the optical signal into an electrical signal indicative of characteristics of a sample analyzed by the device. The present invention further relates generally to a diagnostic system comprising an embodiment of the photosensitive diagnostic device herein described.

In accordance with one embodiment, a photosensitive diagnostic device comprises an illumination source and a detector. The illumination source comprises an output face configured to project an optical signal characterized by at least one diagnostic frequency. The detector comprises a photosensitive input face configured to capture reflected portions of the optical signal. The photosensitive input face of the detector is further configured to convert the captured portions of the optical signal into one or more electrical signals at least partially representing a degree of change in the diagnostic frequency of the optical signal. The output face of the illumination source and the photosensitive input face of the detector lie in a substantially common plane.

In accordance with another embodiment, a photosensitive diagnostic device comprises an illumination source and a detector. The illumination source comprises an output face configured to project an optical signal characterized by at least one diagnostic frequency. The detector comprises a photosensitive input face configured to capture reflected portions of the optical signal. The photosensitive input face of the detector is further configured to convert the captured portions of the optical signal into one or more electrical signals at least partially representing a degree of change in the diagnostic frequency of the optical signal. The output face of the illumination source and the photosensitive input face of the detector lie in a substantially common plane. The output face of the illumination source and the photosensitive input face of the detector are exposed such that the output face and the photosensitive input face are configured to contact a surface of a sample to be analyzed by the device.

In accordance with yet another embodiment, a diagnostic system comprises a photosensitive diagnostic device, a processor, and one or more circuitry components. The photosensitive diagnostic device comprises an illumination source and a detector. The illumination source comprises an output face configured to project an optical signal characterized by at least one diagnostic frequency. The detector comprises a photosensitive input face configured to capture reflected portions of the optical signal. The photosensitive input face of the detector is further configured to convert the captured portions of the optical signal into one or more electrical signals at least partially representing a degree of change in the diagnostic frequency of the optical signal. The output face of the illumination source and the photosensitive input face of the detector lie in a substantially common plane. The processor is configured to analyze the electrical signals of the detector and to present analyses of the electrical signals to an operator of the diagnostic system. The circuitry components are configured to transmit the electrical signals of the detector from the device to the processor.

Accordingly, it is an object of the present invention to present embodiments of a photosensitive diagnostic device. Other objects of the present invention will be apparent in light of the description of the invention embodied herein.

### BRIEF DESCRIPTION OF THE SEVERAL VIEWS OF THE DRAWINGS

The following detailed description of specific embodiments of the present invention can be best understood when read in conjunction with the following drawings, where like structure is indicated with like reference numerals and in which:

FIG. 1 is an illustration of a photosensitive diagnostic device in accordance with one embodiment of the present invention.

FIG. 2 is an illustration of a photosensitive diagnostic device in accordance with one embodiment of the present invention.

### DETAILED DESCRIPTION

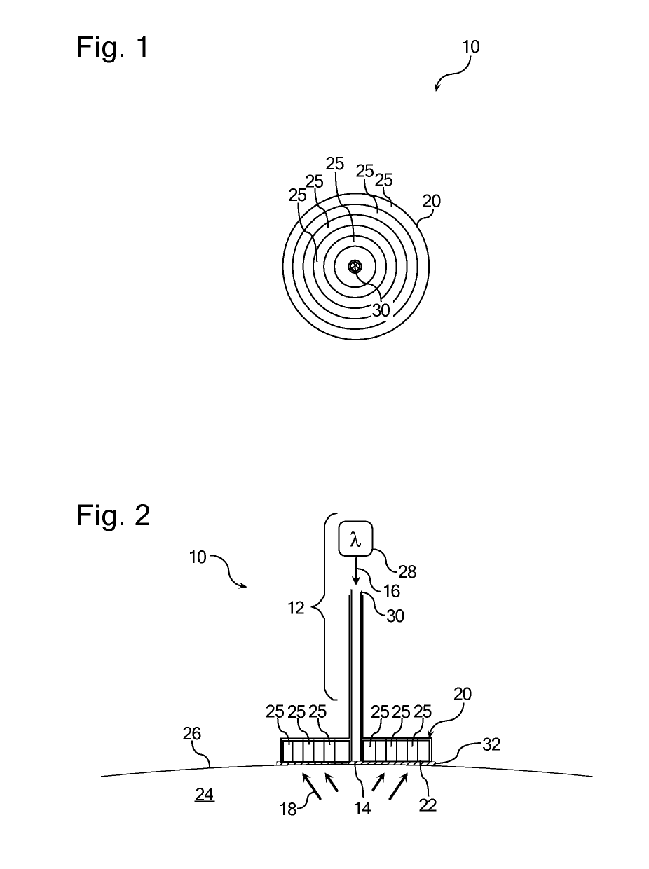

Referring initially to FIG. 1, a photosensitive diagnostic device 10 generally comprises an illumination source 12 and a detector 20. The illumination source 12 comprises an output face 14 that is configured to project an optical signal 16 toward a sample 24 to be analyzed by the device 10. The detector 20, meanwhile, comprises a photosensitive input face 22 that is configured to capture reflected portions 18 of the optical signal 16. The output face 14 of the illumination source 12 and the photosensitive input face 22 of the detector 20 lie in a substantially common plane of the device 10. By positioning the output face 14 and the photosensitive input face 22 in a substantially common plane, the optical signal 16 is projected directly into the sample 24 from the illumination source 12 and the reflected portions 18 of the optical signal 16 emerge from the sample 24 and are immediately captured by the photosensitive input face 22 of the detector 20. As such, there is little or no opportunity for signal loss as the optical signal 16 transitions from the output face 14 to the sample 24 and as the reflected portions 18 of the optical signal 16 transition from the sample 24 to the input face 22 of the detector 20. Further, as will be described in detail below, the input face 22 of the detector 20 can be configured to enhance signal detection in the common plane in which the output and input faces 14, 22 are positioned.

Generally, the output face 14 of the illumination source 12 is placed near, or in direct contact with, the surface 26 of the sample 24 to be analyzed by the device 10. Such positioning of the output face 14 with respect to the surface 26 of the sample 24 substantially reduces the diffusion of the optical signal 16 prior to the optical signal's contact with, and penetration through, the surface 26 of the sample 24. Diffusion of the optical signal 16 generally occurs after the optical signal 16 has projected out from the output face 14 into what is described herein as the surface/air interface. The surface/air interface is a gap that may exist between the surface 26 of the sample 24 and the device 10. The larger the surface/air interface, the greater the diffusion of the optical signal 16.

While diffusion of the optical signal 16 continues after the optical signal 16 penetrates the sample 24, generally to an even greater extent than that occurring in the surface/air interface, placing the output face 14 of the illumination source 12 near, or in direct contact with, the surface 26 of the sample 24 increases both the percentage of the optical signal 16 that contacts the surface 26 of the sample 24 and the percentage of the optical signal 16 that penetrates the sample 24. Typically, a portion of the optical signal 16 that contacts the surface 26 reflects off of the surface 26, rather than penetrate the sample 24. The portion of the optical signal 16 that penetrates the sample 24 generally diffuses throughout the sample 24 to various penetration depths, as will be discussed in greater detail below, and is reflected back toward the surface 26. These reflected portions 18 generally then emerge from the sample 24 through the surface 26 and are captured by the photosensitive input face 22 of the detector 20.

As is noted above, the photosensitive input face 22 of the detector 20 lies in a substantially common plane with the output face 14 of the illumination source 12. As such, diffusion of the reflected portions 18 of the optical signal 16 prior to reaching the photosensitive input face 22 of the detector 20 is also reduced, enabling enhanced capture of the reflected portions 18 of the optical signal 16. As used herein, reflected portions 18 of the optical signal 16 refers to, both individually and in combination, those portions of the optical signal 16 that reflect off of the surface 26 and those portions of the optical signal 16 that penetrate, reflect within the sample 24, and emerge from the sample 24 through the surface 26.

Embodiments of the photosensitive diagnostic device 10 described herein generally are used to analyze humans or other living organisms comprising skin and tissue where generally, but not necessarily, the sample 24 represents the organism, or portion thereof, and the surface 26 represents the skin. It is understood in the art that skin generally has a higher refraction index that of air. As such, as the reflected portions 18 of an optical signal 16 emerge from the skin, some of the reflected portions 18 may refract at a sharp angle and avoid capture by the photosensitive input face 22 positioned near, or in direct contact with, the skin. Such positioning, however, of the input face 22 reduces the surface/air interface between the surface 26 and the device 10. Thereby, positioning the photosensitive input face 22 near, or in direct contact with, the skin substantially reduces the diffusion of the reflected portions 18 of the optical signal 16 after it emerges from the skin. As a result, the photosensitive input face 22 may capture a substantially greater percentage of the reflected portions 18 of the optical signal 16 than when the input face 22 is further removed from the surface 26 of the sample 24 and/or in a plane different from that of the output face 14 of the illumination source 12. For the purposes of defining and describing the present invention, it is noted that two faces lie in a “substantially” common plane when the degree of variance between the respective positions of the two faces is such that any variation in function from precisely coplanar positioning is negligible. For example, and not by way of limitation, it is contemplated that a degree of variation on the order of a few mm would be acceptable.

In accordance with one embodiment, shown in FIG. 2, the output face 14 of the illumination source 12 and the photosensitive input face 22 of the detector 20 are exposed such that the output face 12 and the photosensitive input face 22 are configured to contact the surface 26 of the sample 24 to be analyzed by the device 10. As described above, such an embodiment may substantially increase the percentage of the reflected portions 18 of the optical signal 16 captured by the photosensitive input face 22 of the detector 20.

In accordance with another embodiment, also shown in FIG. 2, the photosensitive input face 22 of the detector 20 comprises an index matching gel 32. This gel 32 may be configured to enhance the capture of the reflected portions 18 of the optical signal 16 by the photosensitive input face 22 of the detector 20. Generally, the gel 32 is applied to the photosensitive input face 22 of the detector 20 substantially in the common plane with the output face 14 of the illumination source 12. As such, the gel 32 is positioned in the surface/air interface between the photosensitive input face 22 of the detector 20 and the surface 26 of the sample 24. The gel 32 may reduce the reflection of the reflected portions 18 of the optical signal 16 from the photosensitive input face 22. More particularly, the index matching gel 32 may be configured to substantially eliminate reflection of the reflected portions 18 of the optical signal 16 from the photosensitive input face 22 of the detector 20 such that the photo sensitive input face 22 captures a greater percentage of the reflected portions 18 of the optical signal 16. Thereby, the gel 32 may enable the input face 22 to achieve a near 100% capturing efficiency of the reflected portions 18 of the optical signal 16. This gel 32 may be configured as any gel commonly used in diagnostic procedures utilizing optical signals 16 that possesses the characteristics and may achieve the desired results described herein.

The illumination source 12 generally comprises a light generating element 28 and a light transmitting element 30. The light generating element 28 may be configured to generate the optical signal 16 projected by the output face 14 of the illumination source 12. The light generating element 28 may comprise, for example, but not by way of limitation, a laser, a broadband laser, a multi-spectral laser, a laser diode, a quantum cascade laser, or various gas lasers. It is contemplated that the light generating element 28 may comprise any optical source capable of producing electromagnetic radiation. The light generating element 28 is coupled to the light transmitting element 30 so as transmit the optical signal 16 generated by the light generating element 28 to the light transmitting element 30. This coupling may be achieved by means known in the art.

The light transmitting element 30 of the illumination source 12 may comprise, for example, but not by way of limitation, an optical fiber, a bundle of optical fibers, a fiber optic plate, or any other conventional or yet to be developed light transmitting element. The light transmitting element 30 generally is configured to transmit the optical signal 16 it receives from the light generating element 28 to the output face 14 of the illumination source 12. As discussed above, the output face 14 is configured to project the optical signal 16, generally towards the sample 24 to be analyzed by the device 10.

The optical signal 16 projected by the output face 14 of the illumination source 12 is characterized by at least one diagnostic frequency. The light generating element 28 of the illumination source 12 generally is configured to generate the optical signal 16 characterized by the at least one diagnostic frequency. This diagnostic frequency of the optical signal 16 is configured to penetrate the sample 24. In accordance with one embodiment, the diagnostic frequency comprises a wavelength range of from about 2.0 μm to about 2.5 μm. Other embodiments contemplate the use of any portion of the electromagnetic spectrum suitable for biological spectroscopic analysis.

Generally, the detector comprises a semiconductor detector. Semiconductor detectors typically capture a high percentage of the reflected portions 18 of the optical signal 16. Further, semiconductor detectors generally require simple mechanical assembly and tend to be relatively inexpensive to manufacture in large volume production. In addition, semiconductor detectors may be configured so as to be compact and mechanically robust such that failure rates tend to be rather low. The detector 20 can be configured as single detector element or as a detector array utilized with an imaging system.

As mentioned above, the detector 20 comprises the photosensitive input face 22 configured to capture the reflected portions 18 of the optical signal 16. The photosensitive input face 22 of the detector 22 is further configured to convert the captured portions of the optical signal 16 into one or more electrical signals. These electrical signals at least partially represent a degree of change in the diagnostic frequency of the optical signal 16. The photosensitive input face 22 of the detector may be configured such that the electrical signals at least partially represent changes in the spectral characteristics of the optical signal 16. Further, the photosensitive input face 22 may be configured such that the electrical signals at least partially represent changes in the amplitude of the optical signal 16. As is described in greater detail herein, the degree of change in the diagnostic frequency, the changes in the spectral characteristics, and/or the changes in the amplitude of the optical signal 16 generally occurs where the diagnostic frequency penetrates the sample 24 to a desired depth to interact with a portion of the sample 24, generally tissue or blood, and provide feedback as to the condition of that portion of the sample 24. For example, but not by way of limitation, the device 10 may be configured to project the diagnostic frequency to penetrate a portion of a circulatory system of an organism and reflect off of glucose particles within the bloodstream. The diagnostic frequency thereby sustains a degree of change indicative of the glucose levels within the bloodstream. It is contemplated that the device 10 may be configured to project the diagnostic frequency to penetrate to any desired penetration depth in the sample 24 and/or to reflect off of other particles within the sample so as to indicate the condition(s) of the particles in question.

The photosensitive input face 22 of the detector 20 generally comprises a plurality of distinct photosensitive elements 25. These photosensitive elements 25 may be configured to generate independent electrical signals, each of which may at least partially represent the degree of change in the diagnostic frequency of the optical signal 16. The plurality of distinct photosensitive elements 25 are provided to the photosensitive input face 22 so as to increase the capturing efficiency of the reflected portions 18 of the optical signal 16 and to indicate the penetration depth of the diagnostic frequency of the optical signal 16 into the sample 24. The photosensitive elements 25 are distinct in that each photosensitive element 25 may be configured to generate a different electrical signal for the reflected portions 18 of the optical signal 16 it captures. Each photosensitive element 25 may generate a different electrical signal according to its respective position on the photosensitive input face 22 of the detector 20. For example, a photosensitive element 25 that is positioned farthest from the output face 14 of the illumination source 12 may generate a distinct electrical signal when capturing reflected portions 18 of the optical signal 16. A photosensitive element 25 positioned farthest from the output face 14 generally will capture only those reflected portions 18 of the optical signal 16 that reflect from the surface 26 or emerge from the sample 24 at that lateral distance from where the substantial portion of the optical signal 16 contacted and penetrated the sample 24.

It is generally understood in the art that the greater the lateral distance from the point of contact and initial penetration of the sample 24 by the optical signal 16 to where a reflected portion 18 of the optical signal 16 emerges from the sample 24, the greater the depth that reflected portion 18 has penetrated into the sample 24. This greater lateral distance from the point of contact and initial penetration generally is attributable to the tissue of the sample 24 that typically widely scatters the optical signal 16.

Therefore, to accurately analyze a condition of a sample 24, or portion thereof, high levels of capturing efficiency of the reflected portions 18 of the optical signal 16 are needed. A photosensitive input face 22 of the detector 20 that covers a broader area of the surface 26 of the sample 24 is likely to have a higher capturing efficiency than that of an input face 22 covering a smaller area of the surface 26 as the input face 22 covering the broader area will capture those reflected portions 18 that have penetrated to greater depths in the sample 24. If so desired, this will provide a more thorough and accurate indication of the conditions of the sample 24.

Generally, the distinct photosensitive elements 25 are arranged in distinct portions of the substantially common plane of the device 10. It is contemplated, however, that one or more photosensitive elements 25 may be arranged in the substantially common plane while another one or more photosensitive elements 25 may be arranged in another plane. Such an embodiment may provide a contoured shape to the device 10 such that the device is configured to more easily or suitably analyze a shaped sample 24.

Further, the distinct photosensitive elements 25 generally are arranged about the output face 14 of the illumination source 12 in the substantially common plane. In accordance with one embodiment, the distinct photosensitive elements 25 are arranged concentrically about the output face 14 of the illumination source 12 in the substantially common plane.

In accordance with another embodiment, shown in FIG. 1, the device 10 is configured such that the output face 14 is centrally positioned within the photosensitive elements 25. Here, the photosensitive elements 25 are arranged on the photosensitive input face 22 of the detector 20 in increments expanding from the centrally positioned output face 14. In this embodiment, the photosensitive elements 25 are arranged on the photosensitive input face 22 of the detector 20 as a series of concentric photosensitive rings about the centrally positioned output face 14. It is contemplated, however, that the photosensitive elements 25 may be arranged on the photosensitive input face 22 of the detector 20 in any variety of arrangements so long as the photosensitive elements 25 may capture reflected portions 18 of an optical signal 16. It is further contemplated that any number of increments of photosensitive elements 25 may be arranged on the input face 22 of the detector such that any desired area of the surface 26 of the sample may be covered, whether by direct contact or not, by the substantially common plane of the device 10.

The photosensitive input face 22 generally is further configured such that at least one of the photosensitive elements 25 is substantially immediately adjacent to at least one of the other photosensitive elements 25, as can be seen in FIGS. 1 and 2. Such an embodiment ensures that substantially no gaps in the substantially common plane are present in the photosensitive input face 22 of the detector 20. This further enhances the capturing efficiency of the reflected portions 18 of the optical signal 16 by the photosensitive input face 22 of the detector 20. In accordance with another embodiment, to further increase capturing efficiency by eliminating gaps in the substantially common plane, the device 10 may be configured such that at least one of the photosensitive elements 25 is substantially immediately adjacent to the output face 14 of the illumination source 12.

In accordance with yet another embodiment, the present invention relates generally to a diagnostic system. This diagnostic system comprises an embodiment of the herein described photosensitive diagnostic device, a suitable processor, and associated circuitry. The particular structure of the processor and circuitry are beyond the scope of the present invention and may be gleaned from conventional or yet to be developed teachings related to processors and circuitry suitable for spectroscopic analysis. Generally, the processor is configured to analyze the electrical signals of the detector 20 and to present analyses of the electrical signals to an operator of the diagnostic system. The circuitry components are configured to transmit the electrical signals of the detector 20 from the device 10 to the processor.

It is contemplated by the embodiments of the present invention that the photosensitive diagnostic device 10 projects and captures various wavelength ranges of various optical signals. As such, the device 10 may be applied to a variety of optical signal reflection, transmission, diffuse scattering, and other optical spectroscopy applications.

For the purposes of defining and describing the present invention, it is noted that the wavelength of “light” or an “optical signal” is not limited to any particular wavelength or portion of the electromagnetic spectrum. Rather, “light” and “optical signals,” which terms are used interchangeably throughout the present specification and are not intended to cover distinct sets of subject matter, are defined herein to cover any wavelength of electromagnetic radiation capable of propagating in an optical wave guide. For example, light or optical signals in the visible and infrared portions of the electromagnetic spectrum are both capable of propagating in an optical waveguide. An optical waveguide may comprise any suitable signal propagating structure. Examples of optical waveguides include, but are not limited to, optical fibers, slab waveguides, and thin-films used, for example, in integrated optical circuits.

It is noted that recitations herein of a component of the present invention being “configured” to embody a particular property, function in a particular manner, etc., are structural recitations, as opposed to recitations of intended use. More specifically, the references herein to the manner in which a component is “configured” denotes an existing physical condition of the component and, as such, is to be taken as a definite recitation of the structural characteristics of the component.

It is noted that terms like “generally,” “commonly,” and “typically” are not utilized herein to limit the scope of the claimed invention or to imply that certain features are critical, essential, or even important to the structure or function of the claimed invention. Rather, these terms are merely intended to highlight alternative or additional features that may or may not be utilized in a particular embodiment of the present invention.

For the purposes of describing and defining the present invention it is noted that the term “substantially” is utilized herein to represent the inherent degree of uncertainty that may be attributed to any quantitative comparison, value, measurement, or other representation. The term “substantially” is also utilized herein to represent the degree by which a quantitative representation may vary from a stated reference without resulting in a change in the basic function of the subject matter at issue. The term “substantially” is further utilized herein to represent a minimum degree to which a quantitative representation must vary from a stated reference to yield the recited functionality of the subject matter at issue.

Having described the invention in detail and by reference to specific embodiments thereof, it will be apparent that modifications and variations are possible without departing from the scope of the invention defined in the appended claims. More specifically, although some aspects of the present invention are identified herein as preferred or particularly advantageous, it is contemplated that the present invention is not necessarily limited to these preferred aspects of the invention.

What is claimed is:

1. A photosensitive diagnostic device comprising an illumination source and a detector, wherein:
the illumination source comprises an output face configured to project an optical signal characterized by at least one diagnostic frequency;
the detector comprises a photosensitive input face configured to capture reflected portions of the optical signal;
the photosensitive input face of the detector is further configured to convert the captured portions of the optical signal into one or more electrical signals at least partially representing a degree of change at the diagnostic frequency of the optical signal; and
the output face of the illumination source and the photosensitive input face of the detector lie in a substantially common plane.

2. The photosensitive diagnostic device of claim 1, wherein the output face of the illumination source and the photosensitive input face of the detector are exposed such that the output face and the photosensitive input face are configured to contact a surface of a sample to be analyzed by the device.

3. The photosensitive diagnostic device of claim 1, wherein the illumination source comprises a light generating element and a light transmitting element.

4. The photosensitive diagnostic device of claim 3, wherein the light generating element comprises a laser, a broadband laser, a multi-spectral laser, a laser diode, a quantum cascade laser, gas laser, or other laser.

5. The photosensitive diagnostic device of claim 3, wherein the light transmitting element of the illumination source comprises an optical fiber, a bundle of optical fibers, a fiber optic plate, or a combination thereof.

6. The photosensitive diagnostic device of claim 3, wherein the light generating element is configured to generate the optical signal characterized by the at least one diagnostic frequency.

7. The photosensitive diagnostic device of claim 6, wherein the diagnostic frequency is configured to penetrate a sample to be analyzed by the device.

8. The photosensitive diagnostic device of claim 1, wherein the diagnostic frequency comprises a wavelength range of from about 2.0 μm to about 2.5 μm.

9. The photosensitive diagnostic device of claim 1, wherein the detector comprises a semiconductor detector.

10. The photosensitive diagnostic device of claim 1, wherein the photosensitive input face of the detector is configured such that the electrical signals at least partially represent changes in the spectral characteristics of the optical signal.

11. The photosensitive diagnostic device of claim 1, wherein the photosensitive input face of the detector is configured such that the electrical signals at least partially represent changes in the amplitude of the optical signal.

12. The photosensitive diagnostic device of claim 1, wherein the photosensitive input face of the detector comprises a plurality of distinct photosensitive elements configured to generate independent electrical signals, each of which may at least partially represent the degree of change at the diagnostic frequency of the optical signal.

13. The photosensitive diagnostic device of claim 12, wherein the distinct photosensitive elements are arranged about the output face of the illumination source in the substantially common plane.

14. The photosensitive diagnostic device of claim 12, wherein the distinctive photosensitive elements are arranged concentrically about the output face of the illumination source in the common plane.

15. The photosensitive diagnostic device of claim 12, wherein the photosensitive input face is configured such that at least one of the photosensitive elements is substantially immediately adjacent to at least one other photosensitive elements.

16. The photosensitive diagnostic device of claim 12, wherein the device is configured such that at least one of the photosensitive elements is substantially immediately adjacent to the output face of the illumination source.

17. The photosensitive diagnostic device of claim 1, wherein the photosensitive input face of the detector comprises an index matching gel configured to:
enhance the capture of the reflected portions of the optical signal by the photosensitive input face of the detector; and
substantially eliminate reflection of the reflected portions of the optical signal from the photosensitive input face of the detector such that the photosensitive input face captures a greater percentage of the reflected portions of the optical signal.

18. The photosensitive diagnostic device of claim 17, wherein the index matching gel is applied to the photosensitive input face of the detector along the substantially common plane.

19. A photosensitive diagnostic device comprising an illumination source and a detector, wherein:
the illumination source comprises an output face configured to project an optical signal characterized by at least one diagnostic frequency;
the detector comprises a photosensitive input face configured to capture reflected portions of the optical signal;
the photosensitive input face of the detector is further configured to convert the captured portions of the optical signal into one or more electrical signals at least partially representing a degree of change at the diagnostic frequency of the optical signal;
the output face of the illumination source and the photosensitive input face of the detector lie in a substantially common plane; and
the output face of the illumination source and the photosensitive input face of the detector are exposed such that the output face and the photosensitive input face are configured to contact a surface of the sample to be analyzed by the device.

20. A diagnostic system comprising:
a photosensitive diagnostic device comprising an illumination source and a detector, wherein:
the illumination source comprises an output face configured to project an optical signal characterized by at least one diagnostic frequency;
the detector comprises a photosensitive input face configured to capture reflected portions of the optical signal;
the photosensitive input face of the detector is further configured to convert the captured portions of the optical signal into one or more electrical signals at least partially representing a degree of change at the diagnostic frequency of the optical signal;
the output face of the illumination source and the photosensitive input face of the detector lie in a substantially common plane;
a processor configured to analyze the electrical signals of the detector and to present analyses of the electrical signals to an operator of the diagnostic system; and
one or more circuitry components configured to transmit the electrical signals of the detector from the device to the processor.
